(19) United States
(12) Patent Application Publication
(10) Pub. No.: US 2026/0291092 A1
(43) Pub. Date: Sep. 24, 2026

(54) ELECTRONIC MODULE AND METHOD OF MANUFACTURING ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/478,265

(22) PCT Filed: Apr. 17, 2024
(86) PCT No.: PCT/JP2024/015218

§ 371 Date: Oct. 24, 2025

(30) Foreign Application Priority Data
Apr. 28, 2023 (JP) 2023-074804

(51) Int. Cl. H01R 12/58; H01R 43/02; H05K 1/181

(52) U.S. Cl. CPC H01R 12/585; H01R 43/0256; H05K 1/181; H05K 2201/10166

(57) ABSTRACT

An electronic module includes: an electronic element, a support member in which a through hole that penetrates the support member in a plate thickness direction is formed, and a pin terminal having a columnar shape, the pin terminal being supported on the support member in a state that the pin terminal is made to pass through the through hole and being electrically connected with the electronic element. The pin terminal includes: a pin body, and an electrically conductive peel-off material that is disposed on a surface of the pin body, and the pin terminal is supported by the support member in a state where the electrically conductive peel-off material is interposed at least at a portion between the through hole and the pin body.

### RELATED APPLICATIONS

This application is a National Phase of International Application No. PCT/JP2024/015218 filed Apr. 17, 2024, which claims priority based on Patent Application 2023-074804 filed in Japan on Apr. 28, 2023, and the entire contents Of the application are incorporated herein by reference.

### TECHNICAL FIELD

The present invention relates to an electronic module, and a method of manufacturing an electronic module.

### BACKGROUND ART

Conventionally, there has been known an electronic module (for example, a semiconductor device) that includes: an electronic element (for example, a semiconductor chip); a support member (for example, a lead frame) in which a through hole is formed in a plate thickness direction; and a pin terminal having a columnar shape that is supported in a state where the pin terminal passes through the through hole formed in the support member, and is electrically connected with the electronic element (for example, Patent Literature 1).

### PRIOR ART LITERATURE

### Patent Literature

[Patent literature 1] WIPO 2020/208741

### SUMMARY OF INVENTION

### Technical Problem

The conventional electronic module is manufactured via a step of fitting the pin terminal into the through hole formed in the support member by press fitting. In this step, it is necessary to strictly control a dimensional tolerance relating to a diameter of the pin terminal and a size of the through hole. That is, in a case where the diameter of the pin terminal is excessively small or the through hole is excessively large, the pin terminal cannot be properly fixed by the support member so that there is a case where the pin terminal is inclined or the pin terminal is removed. Further, in a case where the diameter of the pin terminal is excessively large or the through hole is excessively small, there may be a case where the press fitting is stopped halfway or the support member is deformed so that a pressure required for press fitting becomes large.

The present invention has been made in view of the above-mentioned drawbacks, and it is an object of the present invention to provide an electronic module that can alleviate accuracy of a control of dimensional tolerance relating to a diameter of a pin terminal and a size of a through hole. Further, it is another object of the present invention to provide a method of manufacturing such an electronic module.

### Solution to Problem

An electronic module according to the present invention is an electronic module that includes: an electronic element; a support member in which a through hole that penetrates the support member in a plate thickness direction is formed; and a pin terminal having a columnar shape, the pin terminal being supported on the support member in a state that the pin terminal is made to pass through the through hole and being electrically connected with the electronic element, wherein the pin terminal includes: a pin body; and an electrically conductive peel-off material that is disposed on a surface of the pin body, and the pin terminal is supported by the support member in a state where the electrically conductive peel-off material is interposed at least at a portion between the through hole and the pin body.

A method of manufacturing an electronic module according to the present invention is a method of manufacturing an electronic module for manufacturing an electronic module that includes: an electronic element; a support member in which a through hole that penetrates the support member in a plate thickness direction is formed; and a pin terminal having a columnar shape, the pin terminal being supported on the support member in a state that the pin terminal is made to pass through the through hole and being electrically connected with the electronic element. The method of manufacturing an electronic module includes: a pin terminal press fitting step of fitting the pin terminal having a pin body and an electrically conductive peel-off material that is disposed on a surface of the pin body into the through hole formed in the support member by press fitting, wherein in the pin terminal press fitting step, the pin terminal is fitted into the through hole formed in the support member while peeling off a portion of the electrically conductive peel-off material by a peripheral edge of the through hole.

### Advantageous Effects of the Present Invention

In the electronic module according to the present invention, the pin terminal includes: the pin body; and the electrically conductive peel-off material that is disposed on the surface of the pin body, and the pin terminal is supported by the support member in a state where the electrically conductive peel-off material is interposed at least at a portion between the through hole and the pin body. In the electronic module of the present invention, at the time of manufacturing the electronic module (at the time of fitting the pin terminal into the through hole formed in the support member by press fitting), the electrically conductive peel-off material to be peeled off exists, and the shape of the pin terminal after press fitting conforms to the through hole formed in the support member due to peeling off of the electrically conducive peel-off material. Accordingly, it is unnecessary to strictly control the diameter of the pin terminal that includes a thickness of the electrically conducive peel-off material and hence, it is possible to provide the electronic module that can alleviate accuracy of a control of the dimensional tolerance relating to a diameter of the pin terminal and a size of the through hole.

In the method of manufacturing an electronic module according to the present invention, the method includes the pin terminal press fitting step of fitting the pin terminal having the pin body and the electrically conductive peel-off material that is disposed on the surface of the pin body into the through hole formed in the support member by press fitting, and in the pin terminal press fitting step, the pin terminal is fitted into the through hole formed in the support member while peeling off a portion of the electrically conductive peel-off material by the peripheral edge of the through hole. In the method of manufacturing an electronic module according to the present invention, the pin terminal having the electrically conductive peel-off material that is peeled off when the pin terminal is fitted into the through hole formed in the support member by press fitting is used and hence, the shape of the pin terminal after press fitting conforms to the through hole formed in the support member due to peeling off of the electrically conductive peel-off material. Accordingly, it is unnecessary to strictly control the diameter of the pin terminal that includes a thickness of the electrically conducive peel-off material and hence, it is possible to provide the method of manufacturing an electronic module that can alleviate accuracy of a control of the dimensional tolerance relating to a diameter of the pin terminal and a size of the through hole.

### BRIEF DESCRIPTION OF DRAWINGS

FIG. 1 is a perspective view of an electronic module 100 according to an embodiment.

FIG. 2A to FIG. 2C are external appearance views of the electronic module 100 according to the embodiment.

FIG. 3 is a view illustrating an internal structure of the electronic module 100 according to the embodiment.

FIG. 4A to FIG. 4D are views illustrating a support member 171 and a pin terminal 172 in the embodiment.

FIG. 5 is a flowchart of a method of manufacturing an electronic module according to the embodiment.

FIG. 6A to FIG. 6D are views illustrating a pin terminal press fitting step electrically conductive bonding material melting step S30.

### DESCRIPTION OF EMBODIMENTS

Hereinafter, an electronic module and a method of manufacturing an electronic module according to the present invention are described. The embodiment described hereinafter is not intended to limit the invention called for in claims. Further, it is not always the case that various elements and all combinations of these elements described in the embodiment are indispensable for the present invention.

### Embodiment

### 1. Electronic Module

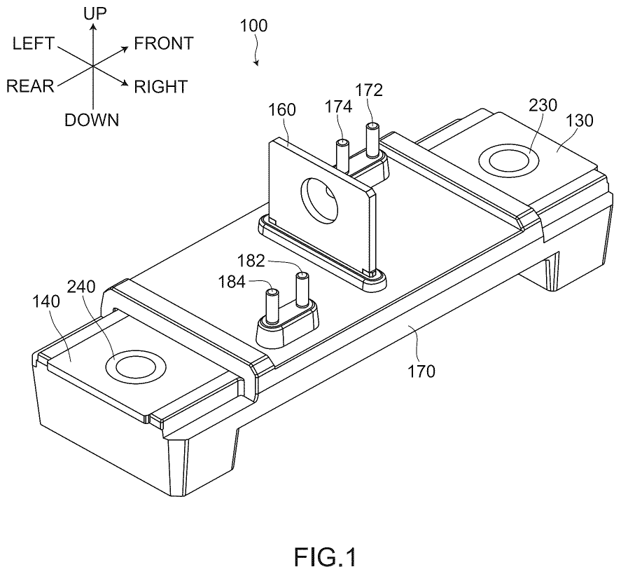

FIG. 1 is a perspective view of an electronic module 100 according to an embodiment.

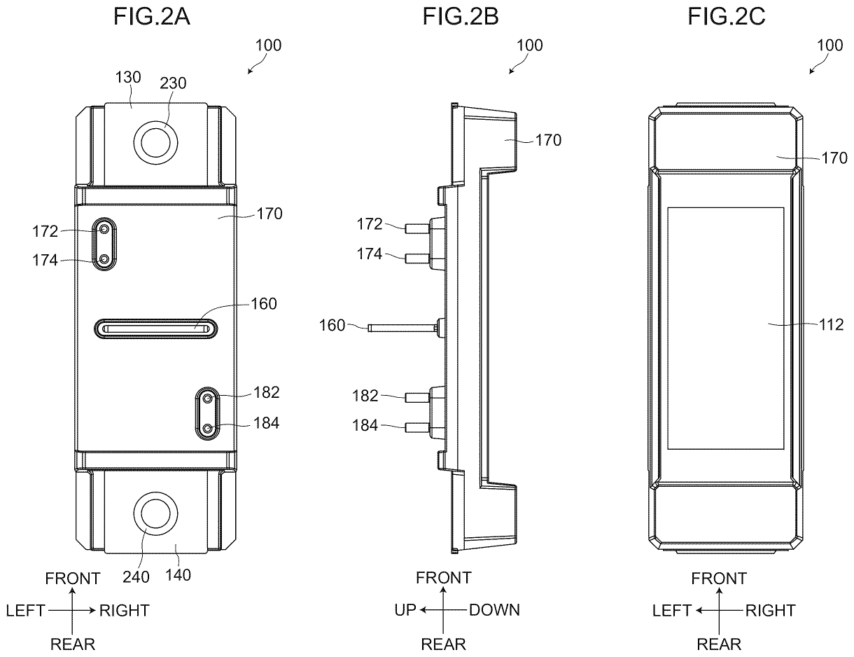

FIG. 2A to FIG. 2C are external appearance views of the electronic module 100 according to the embodiment. FIG. 2A is a plan view of the electronic module 100, FIG. 2B is a side view of the electronic module 100, and FIG. 2C is a bottom plan view of the electronic module 100.

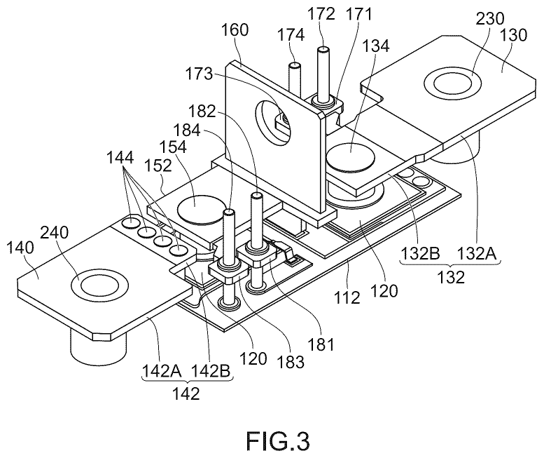

FIG. 3 is a view illustrating an internal structure of the electronic module 100 according to the embodiment.

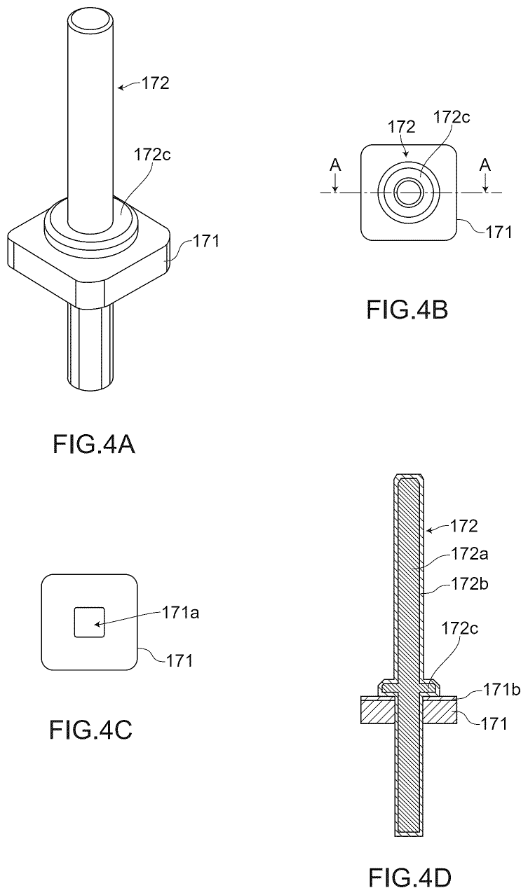

FIG. 4A to FIG. 4D are views illustrating a support member 171 and a pin terminal 172 in the embodiment. FIG. 4A is a perspective view of the support member 171 and the pin terminal 172, FIG. 4B is a plan view of the support member 171 and the pin terminal 172, FIG. 4C is a plan view of the support member 171, and FIG. 4D is a cross-sectional view taken along a line A-A in FIG. 4B.

In the description made hereinafter, as illustrated in FIG. 1 and FIG. 2A to FIG. 2C, the description is made by setting a longitudinal direction of the electronic module 100 as a front-rear direction, and a lateral direction as a left-and-right direction. Further, the description is made by setting a height direction of the electronic module 100 as an up-down direction. The terms “front”, “rear”, “left”, “right”, “up” and “down” in the description made hereinafter are used for the sake of convenience of the description, and do not specify the direction that the electronic module 100 is mounted when the electronic module 100 is used.

As illustrated in FIG. 1 to FIG. 3, the electronic module 100 is elongated in the front-rear direction, and is formed in an approximately rectangular parallelepiped body shape that is flat in the up-down direction. The electronic module 100 includes an electronic element 120, a first terminal 130, a second terminal 140, a first wiring 132B, a second wiring 142B, a first cap nut 230, a second cap nut 240, support members 171, 173, 181, 183, pin terminals 172, 174, 182, 184, and a sealing resin 170.

In the description made hereinafter, “the first cap nut 230 and the second cap nut 240” may be also referred to as “cap nuts 230, 240”.

As the electronic element 120, for example, a power metal-oxide-semiconductor field-effect transistor (MOSFET) can be used. The electronic element 120 may be disposed on one surface of a circuit board 112. The electronic element 120 is constituted as a semiconductor element, for example, and includes electrodes (not illustrated in the drawing) that is formed on one surface or both surfaces of the semiconductor board. The electronic module 100 includes two electronic elements 120.

The circuit board 112 is, for example, a ceramic board that is manufactured by direct copper bonding (DCB) where a conductive region (circuit) is formed on an upper surface of the ceramic board and a metal plate for heat dissipation is formed on a lower surface (back surface) of the ceramic board. The circuit board 112 may be a printed circuit board or the like. The circuit board 112 is formed in a rectangular planner shape, and is disposed at a center portion of the electronic module 100 in a front-rear direction that is a longitudinal direction.

As illustrated in FIG. 1 to FIG. 3, the first terminal 130 is disposed on a front side of the electronic module 100 in the front-rear direction. The first terminal 130 is constituted of a plate member 132A formed of a flat plate member having electrically conductive property, for example, a copper plate. The first terminal 130 has a through hole (symbol being omitted) that penetrates the first terminal 130 in the up-down direction. The through hole has, for example, a circular shape as viewed in the up-down direction. The shape of the through hole is not limited to a circular shape, and may be a polygonal shape such as a hexagonal shape.

An upper end of the first cap nut 230 engages with the through hole by fitting engagement. In this case, it is preferred that a height of an upper surface of the first cap nut 230 is equal to a height of an upper surface of the first terminal 130, or lower than the height of the upper surface of the first terminal 130.

The lower surface of the first terminal 130 and the first cap nut 230 are embedded in the sealing resin 170. On the other hand, the upper surface of the first terminal 130 is exposed to the outside of the sealing resin 170. By arranging the external connecting member (not illustrated in the drawing) on the upper surface of the first terminal 130 that is exposed from the sealing resin 170 and by fixing the external connecting member to the upper surface of the first terminal 130 by a bolt (not illustrated in the drawing), the electrical connection can be established between the first terminal 130 and the external connecting member.

The first wiring 132B is electrically connected with the first terminal 130. The first wiring 132B is embedded in the sealing resin 170. In the electronic module 100, the first wiring 132B is integrally formed with the first terminal 130 using the same plate member 132. That is, a portion of the plate member 132 that is embedded in the sealing resin 170 corresponds to the first wiring 132B.

The first wiring 132B has a through hole (symbol being omitted) that vertically penetrates the first wiring 132B. The through hole is formed in a circular shape as viewed in the up-down direction. An upper end portion of an internal connection electrode 134 engages with the through hole by fitting engagement. The first wiring 132B and an electrode of the electronic element 120 are connected with each other by the internal connection electrode 134. The internal connection electrode 134 is fixed to the first wiring 132B by press fitting, for example.

As illustrated in FIG. 1 to FIG. 3, the second terminal 140 is disposed on a rear side of the electronic module 100 in the front-rear direction. The second terminal 140 is constituted of a plate member 142A formed of a flat plate member having electrically conductive property, for example, a copper plate. The second terminal 140 has a through hole (symbol being omitted) that penetrates the second terminal 140 in the up-down direction. The through hole has, for example, a circular shape as viewed in the up-down direction. The shape of the through hole is not limited to a circular shape, and may be a polygonal shape such as a hexagonal shape.

An upper end of the second cap nut 240 engages with the through hole by fitting engagement. In this case, it is preferred that a height of an upper surface of the second cap nut 240 is equal to a height of an upper surface of the second terminal 140, or lower than the height of the upper surface of the second terminal 140.

The lower surface of the second terminal 140 and the second cap nut 240 are embedded in the sealing resin 170. On the other hand, the upper surface of the second terminal 140 is exposed to the outside of the sealing resin 170. By arranging the external connecting member (not illustrated in the drawing) on the upper surface of the second terminal 140 that is exposed from the sealing resin 170 and by fixing the external connecting member to the upper surface of the second terminal 140 by the bolt (not illustrated in the drawing), the electrical connection can be established between the second terminal 140 and the external connecting member.

The second wiring 142B is electrically connected with the second terminal 140. The second wiring 142B is embedded in the sealing resin 170.

In the electronic module 100, the second wiring 142B is integrally formed using the same plate member 142 as the second terminal 140. That is, a portion of the plate member 142 that is embedded in the sealing resin 170 corresponds to the second wiring 142B.

The second wiring 142B has four through holes (symbols being omitted) that penetrate the second wiring 142B in the up-down direction. The through holes are formed in a circular shape as viewed in the up-down direction. An upper end portion of an internal connection electrode 144 engages with each of four through holes by fitting engagement. The second wiring 142B and electrodes (not illustrated in the drawing) of the electronic element 120 are connected with each other by four internal connection electrodes 144. The internal connection electrodes 144 are fixed to the second wiring 142B by press fitting, for example. The number of the above-mentioned through holes and the number of the above-mentioned internal connection electrodes 144 can be respectively set to an arbitrary number of one or more without being limited to four provided that the flow of required electricity is allowed.

The electronic module 100 may include a third terminal 160. The third terminal 160 is an arbitrary constitutional element. As illustrated in FIG. 1 to FIG. 3, the third terminal 160 is formed of a flat plate member having electrically conductive property, for example, a copper plate. The third terminal 160 is arranged such that a plate thickness direction is the front-rear direction, and is formed in an elongated shape with the upper-down direction set as the longitudinal direction. The third terminal 160 has a portion that is disposed on an upper side of the sealing resin 170 and is exposed from the sealing resin 170 (hereinafter referred to as “upper side portion”), and a portion covered by the sealing resin 170 (hereinafter referred to as “lower side portion”).

A through hole (symbol being omitted) that penetrates the third terminal 160 in the front-rear direction is formed in an upper side portion of the third terminal 160. With such a configuration, an external connecting member (not illustrated in the drawing) can be fixed to the third terminal 160 by a bolt (not illustrated in the drawing) and a nut (not illustrated in the drawing). Further, one end of a cap nut (not illustrated in the drawing) may engage with the through hole by fitting engagement. With such a configuration, in a state where the external connecting member is fixed to the third terminal 160 by the bolt, it is possible to establish an electrical connection between the third terminal 160 and the external connecting member with certainty.

A lower side portion of the third terminal 160 is connected with an electrode (not illustrated in the drawing) of the electronic element 120.

The electronic module 100 may include a third wiring 152. The third wiring 152 is an arbitrary constitutional element. The third wiring 152 is electrically connected with the third terminal 160. The third wiring 152 may be disposed on the same plane as the first wiring 132B and the second wiring 142B.

The third wiring 152 has a through hole (symbol being omitted) that penetrates the third wiring 152 in the up-down direction. The through hole has a circular shape as viewed in the vertical direction. An upper end portion of an internal connection electrode 154 engages with the through hole by fitting engagement. The third wiring 152 and an electrode (not illustrated in the drawing) of the electronic element 120 are connected with each other by the internal connection electrode 154. The internal connection electrode 154 is fixed to the third wiring 152 by press fitting, for example.

The support members 171, 173, 181, 183 and the pin terminals 172, 174, 182, 184 have substantially the same configuration respectively. Accordingly, only the structure of the support member 171 and the structure of the pin terminal 172 are described in detail (see FIG. 4A to FIG. 4D).

A through hole 171a that penetrates the support member 171 in a plate thickness direction is formed in the support member 171 (see FIG. 4C). The through hole 171a has a square shape as viewed in a plan view. The support member 171 is manufactured by applying press forming to a flat-plate-shaped member having electrically conductive property, for example, a copper plate. Further, although the illustration is omitted in FIG. 4A to FIG. 4C, it is preferred that an electrically conductive bonding material 171b that is made of solder or the like is disposed on at least one surface of the support member 171 (see FIG. 4D). It is preferred that the conductive bonding material 171b bonds the support member 171 and the pin terminal 172 to each other in a state where the flow of electricity is allowed.

The pin terminal 172 is supported by the support member 171 in a state where the pin terminal 172 is made to pass through the through hole 171a, and is electrically in contact with the electronic element 120. The electrical connection between the pin terminal 172 and the electronic element 120 may be realized by a direct contact between the pin terminal 172 and the electronic element 120, may be realized via an electrically conductive region (circuit) that is formed on the circuit board 112, or may be realized via the support member 171.

The pin terminal 172 has a columnar shape. The pin terminal 172 has a pin body 172a, and an electrically conductive peel-off material 172b that is disposed on a surface of the pin body 172a (see FIG. 4D). The pin terminal 172 is supported by the support member 171 in a state where the electrically conductive peel-off material 172b is interposed at least at a portion between the through hole 171a and the pin body 172a. The pin terminal 172 further has a flange portion 172c that is in contact with the support member 171.

The pin body 172a is a member having a circular columnar shape that is made of a material having electrically conductive property, for example, copper. The flange portion 172c is a member having a disk shape made of a material having electrically conductive property, for example, copper. The pin body 172a and the flange portion 172c of the pin terminal 172 are formed as an integral body. However, the pin body 172a and the flange portion 172c may be formed as separated bodies from each other.

The electrically conductive peel-off material 172b is disposed so as to cover the entire surface of the pin body 172a and the entire surface of the flange portion 172c. It is preferred that electrically conductive peel-off material 172b is made of a plating material. It is preferred that the electrically conductive peel-off material 172b is made of Ni, Au, Pd, Sn, Ag, or solder. Further, it is preferred that the electrically conductive peel-off material 172b is made of a material having hardness lower than hardness of the pin body 172a.

In this specification, “solder” means an electrically conductive bonding material in general that is used for the electrical connection of an electronic part, and includes so-called lead-free solder besides conventional solder containing lead.

In FIG. 4D, it is illustrated that the conductive bonding material 171b of the support member 171 and the electrically conductive peel-off material 172b of the pin terminal 172 are formed as separate bodies from each other. However, the conductive bonding material 171b and the electrically conductive peel-off material 172b may be integrally formed with each other.

The pin terminals 172, 174, 182, 184 each have: a portion disposed so as to protrude above the sealing resin 170 and is exposed from the sealing resin 170; and a portion that is covered by the sealing resin 170. The portions of the pin terminals 172, 174, 182, 184 that are covered by the sealing resin 170 are electrically connected with electrodes of the electronic element 120. Further, the portions of the pin terminals 172, 174, 182, 184 that protrude from the sealing resin 170 can be connected with external connection members (not illustrated in the drawing).

Cap nuts 230, 240 are each formed of a nut where one surface of the nut is closed so that a threaded hole does not penetrate. The shape of a portion of each of the cap nuts 230, 240 that engages with the first terminal 130 or the second terminal 140 by fitting engagement is not limited so long as the portion of each of the cap nuts 230, 240 conforms with a shape of the through hole formed in the first terminal 130 or the second terminal 140. The shape of the portion may be a polygonal shape such as a hexagonal shape besides a circular shape illustrated in FIG. 1 to FIG. 3.

The sealing resin 170 seals the electronic element 120, the lower surface of the first terminal 130, a lower surface of the second terminal 140, the first wiring 132B, the second wiring 142B, the first cap nut 230, and the second cap nut 240. On the other hand, a portion of the member (circuit board 112) on which the electronic element 120 is disposed may be exposed from the sealing resin 170. The sealing resin 170 is made of a thermosetting molding material which contains an epoxy resin as a main component and to which a silica filler or the like is added. The sealing resin 170 protects the electronic element 120 from an environment such as heat, light, humidity and the like.

### 2. Method of Manufacturing Electronic Module

Next, a method of manufacturing the electronic module according to the embodiment is described.

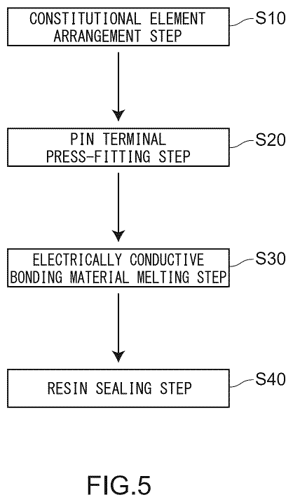

FIG. 5 is a flowchart of a method of manufacturing the electronic module according to the embodiment.

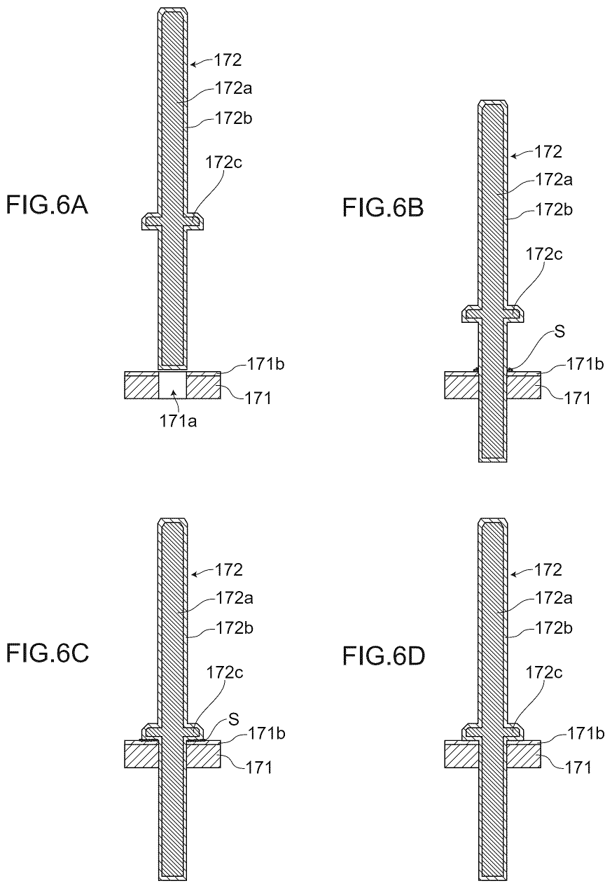

FIG. 6A to FIG. 6D are views illustrating a pin terminal press fitting step S20 and an electrically conductive bonding material melting step S30. FIG. 6A to FIG. 6C are step views of the pin terminal press fitting step S20, and FIG. 6D is a view illustrating the support member 171 and the pin terminal 172 after the electrically conductive bonding material melting step S30. FIG. 6A to FIG. 6D are cross-sectional views as viewed in the same manner as the cross section in FIG. 4D.

The method of manufacturing an electronic module according to an embodiment is a method of manufacturing the electronic module 100, and includes: a constitutional element arrangement step S10; the pin terminal press-fitting step S20; a resin sealing step S40. The method of manufacturing an electronic module according to an embodiment further includes the electrically conductive bonding material melting step S30 when necessary (see FIG. 5). Hereinafter, the respective steps are described.

The constitutional element arrangement step S10 is a step of arranging constitutional elements of the electronic module 100 (excluding the pin terminals 172, 174, 182, 184 and the sealing resin 170) at predetermined positions. A known method can be used with respect to the arrangement of the respective constitutional elements and hence, the description of the arrangement of the respective constitutional elements is omitted.

The pin terminal press-fitting step S20 is a step relating to the support members 171, 173, 181, 183 and the pin terminals 172, 174, 182, 184. However, the description of these members and terminals is made by using the support member 171 and the pin terminal 172 as the representing member and the representing terminal. The materials and the configurations of the support member 171 and the pin terminal 172 have been already described and hence, the repeated explanation is omitted.

The pin terminal press-fitting step S20 is a step of fitting the pin terminal 172 that has the pin body 172a and the electrically conductive peel-off material 172b disposed on a surface of the pin body 172a into the through hole 171a formed in the support member 171 by press fitting (see FIG. 6A to FIG. 6D). For the sake of facilitating the molding of the constitutional elements and the fixing of the constitutional elements at positions, it is preferred that the steps ranging from the constitutional element arrangement step S10 to the resin sealing step S40 are advanced in a state where the support member 171 is connected to a frame (not illustrated in the drawing) that is a metal-made frame. However, this is a matter known in general and hence, the detailed description and illustration of the molding and the fixing of the constitutional elements at positions are omitted.

First, the pin terminal 172 is arranged such that a bottom portion of the pin terminal 172 approaches an area in the vicinity of the through hole 171a formed in the pin terminal 172 (see FIG. 6A). Next, a pressure is applied to the pin terminal 172 such that the pin terminal 172 is fitted into the through hole 171a by press fitting. (see FIG. 6B). The pin terminal 172 is fitted into the through hole 171a by fitting engagement until the bottom portion of the pin terminal 172 is brought into contact with the circuit board 112 (not illustrated in FIG. 6A to FIG. 6D) or the flange portion 172c is brought into contact with the support member 171 (see FIG. 6C).

In the pin terminal press-fitting step S20, the pin terminal 172 is fitted into the through hole 171a formed in the support member 171 by press fitting while peeling off a portion of the electrically conductive peel-off material 172b by a peripheral edge of the through hole 171a. The electrically conductive peel-off material 172b that is peeled off at the time of fitting the pin terminal 172 by press fitting forms peeled-off chips S, and the peeled-off chips S fall on the support member 171 (see FIG. 6B). In the pin terminal press-fitting step S20, as the support member 171, it is preferred to use a support member having a surface on which the electrically conductive bonding material 171b is disposed. The electrically conductive bonding material 171b is disposed on a side where the pin terminal 172 is disposed. In this case, the peeled-off chips S fall on the electrically conductive bonding material 171b. In the method of manufacturing an electronic module, the term “electrically conductive bonding material” includes a precursor of an electrically conductive material (a material that is transformed into an electrically conductive bonding material by melting and solidifying or the like performed after melting, including a solder paste, for example).

It is preferred that a thickness of the electrically conductive peel-off material 172b before the pin terminal 172 is fitted into the through hole 171a by press fitting is within a range of from 10 μm or more and two times or less of a maximum diameter of the pin body 172a. Further, it is preferred that the maximum diameter of the pin body 172a is smaller than a size of the through hole 171a, and a maximum diameter of the pin terminal 172 including the electrically conductive peel-off material 172b is larger than the size of the through hole 171a. To further describe the configuration, it is preferred that the maximum diameter of the pin terminal 172 including the electrically conductive peel-off material 172b is larger than the size of the through hole 171a within a range of from 1 μm to 50 μm.

In this specification, the term “a maximum diameter of the pin body” means a maximum diameter of a portion of the pin body that passes through the through hole at the time of performing press fitting. Further, in this specification, “a size of the through hole” corresponds to a length of a shortest straight line out of shortest straight lines each of which connects one point and the other point on the peripheral edge of the through hole and passes the center of the through hole. For example, as in the case of the embodiment where the through hole 171a has a square shape, the size of the through hole does not correspond to a length between opposedly facing corners (a length of a diagonal line) but corresponds to a length between opposedly facing sides.

In accordance with a method substantially equal to the method described above, the pin terminals 174, 182, 184 can be also fitted into the through holes formed in the support members 173, 181, 183 by press fitting respectively.

Although the press fitting of the pin terminal 172 into the through hole 171a is completed by the pin terminal press-fitting step S20 described above, at this stage of the manufacturing method, the bonding between the support member 171 and the pin terminal 172 using the electrically conductive bonding material 171b has not been performed. Further, the peeled-off chips S are kept fallen on the electrically conductive bonding material 171b, and the entire peeled-off chips S or a part of the peeled-off chips S are in a state of being sandwiched between the support member 171 and the flange portion 172c (see FIG. 6(c)). Accordingly, it is preferred that the method of manufacturing an electronic module according to the embodiment further includes the electrically conductive bonding material melting step S30 (also can be referred to as a reflow step) where the support member 171 and the pin terminal 172 are bonded to each other by melting the electrically conductive bonding material 171b after the pin terminal press-fitting step S20. The electrically conductive bonding material melting step S30 is a step consisting of: heating the electrically conductive bonding material 171b until the electrically conductive bonding material 171b is melted; and solidifying the electrically conductive bonding material 171b. A heating temperature and a heating time in the electrically conductive material melting step S30 are suitably determined based on a kind of the electrically conductive bonding material 171b and heat resistances of the constitutional elements that form the electronic module 100.

In accordance with the above-mentioned steps, the support member 171 and the pin terminal 172 can be electrically bonded to each other with certainty and, at the same time, it is possible to enable the electrically conductive bonding material 171b, the electrically conductive peel-off material 172b, or both of the electrically conductive bonding material 171b and the electrically conductive peel-off material 172b to absorb the peeled-off chips S that are peeled off in the pin terminal press-fitting step S20 (see FIG. 6(d)). From a viewpoint of efficiency, it is preferred that the electrically conductive bonding material melting step S30 is performed after the press-fitting of all pin terminals 172, 174, 182, 184 is completed. The electrically conductive bonding material melting step S30 may be a step of bonding by a conductive bonding material or the like also with respect to constitutional elements of the electronic module 100 (the constitutional elements other than the pin terminals 172, 174, 182, 184) that are arranged in advance.

The resin sealing step S40 is a step of sealing portions that require sealing by the sealing resin 170. A known method can be used with respect to resin sealing and hence, the description of the resin sealing step S40 is omitted.

By performing the above-mentioned steps, it is possible to manufacture the electronic module 100 according to the embodiment.

### 3. Advantageous Effects Acquired by the Electronic Module 100 and the Method Of Manufacturing an Electronic Module According to Embodiment

In the electronic module 100 according to the embodiment, the pin terminals 172, 174, 182, 184 each include: the pin body; and the electrically conductive peel-off material that is disposed on the surface of the pin body, and the pin terminals 172, 174, 182, 184 are supported by the support members 171, 173, 181, 183 in a state where the electrically conductive peel-off material is interposed at least at a portion between the through hole and the pin body. In the electronic module of the present embodiment, at the time of manufacturing the electronic module 100 (at the time of fitting the pin terminals 172, 174, 182, 184 into the through holes formed in the support members 171, 173, 181, 183 by press fitting), the electrically conductive peel-off material to be peeled off exists, and the shapes of the pin terminals 172, 174, 182, 184 after press fitting conform to the through holes formed in the support members 171, 173, 181, 183 due to peeling off of the electrically conducive peel-off material. Accordingly, it is unnecessary to strictly control the diameters of the pin terminals 172, 174, 182, 184 each of which includes a thickness of the electrically conducive material and hence, it is possible to provide the electronic module that can alleviate the degree of accuracy of a control of the dimensional tolerance relating to the diameters of the pin terminals 172, 174, 182, and sizes of the through holes.

In the method of manufacturing an electronic module according to the present invention, the method includes the pin terminal press fitting step S20 of fitting the pin terminals 172, 174, 182, 184 having the pin body and the electrically conductive peel-off material that is disposed on the surface of the pin body into the through holes formed in the support members 171, 173, 181, 183 by press fitting, and in the pin terminal press fitting step S20, the pin terminals 172, 174, 182, 184 are fitted into the through holes formed in the support members 171, 173, 181, 183 while peeling off a portion of the electrically conductive peel-off material by a peripheral edge of the through hole. In the method of manufacturing an electronic module according to the embodiment, the pin terminals 172, 174, 182, 184 each having the electrically conductive peel-off material that is peeled off when the pin terminals 172, 174, 182, 184 are fitted into the through holes formed in the support members 171, 173, 181, 183 are used and hence, the shape of each of the pin terminals 172, 174, 182, 184 after press fitting conforms to the through hole formed in each of the support members 171, 173, 181, 183 due to peeling off of the electrically conductive peel-off material. Accordingly, it is unnecessary to strictly control the diameter of each of the pin terminals 172, 174, 182, 184 that includes a thickness of the electrically conducive peel-off material and hence, it is possible to provide the method of manufacturing an electronic module that can alleviate the degree of accuracy of a control of the dimensional tolerance relating to diameters of the pin terminals 172, 174, 182, 184 and sizes of the through holes.

According to the method of manufacturing an electronic module according to the embodiment, in a case where the electrically conductive peel-off material is made of a plating material, with respect to the pin terminals 172, 174, 182, 184, the electrically conductive peel-off material is relatively uniformly disposed on a surface of the pin body and hence, it is possible to perform the fitting of the pin terminals 172, 174, 182, 184 by press fitting in a stable manner.

According to the method of manufacturing an electronic module according to the embodiment, in a case where the electrically conductive peel-off material is made of Ni, Au, Pd, Sn, Ag or solder, with the use of the material having a sufficient electrically conductive property as the electrically conductive peel-off material, it is possible to suppress or prevent lowering of electrically conductive property by disposing the electrically conductive peel-off material.

According to the method of manufacturing an electronic module of the embodiment, in a case where the electrically conductive peel-off material is made of a material having hardness lower than hardness of the pin body, peeling (shaving) of the electrically conductive peel-off material at the time of fitting the pin terminals 172, 174, 182, 184 by press fitting is facilitated and hence, it is possible to prevent a state that an excessively large pressure is applied to the pin terminals 172, 174, 182, 184.

According to the method of manufacturing an electronic module of the embodiment, in a case where a thickness of the electrically conductive peel-off material before pin terminals 172, 174, 182, 184 are fitted into the through hole by press fitting falls within a range of from 10 μm or more to two times or less of a maximum diameter of the pin body, the thickness of the electrically conductive peel-off material is set to 10 μm or more and hence, it is possible to allow the electrically conductive peel-off material to secure a sufficient thickness and, at the same time, the thickness of the electrically conductive peel-off material is set to two times or less of the maximum diameter of the pin body and hence, it is possible to prevent supporting of the pin terminals 172, 174, 182, 184 by the support members 171, 173, 181, 183 after press fitting from becoming unstable.

According to the method of manufacturing an electronic module of the embodiment, in a case where a maximum diameter of the pin body is smaller than a size of the through hole, and a maximum diameter of the pin terminal 172, 174, 182, 184 including the electrically conductive peel-off material is larger than the size of the through hole, it is possible to secure a contact between the support members 171, 173, 181, 183 and the pin terminals 172, 174, 182, 184 while facilitating passing of the pin body through the through hole.

According to the method of manufacturing an electronic module of the embodiment, in a case where a maximum diameter of each of the pin terminals 172, 174, 182, 184 including the electrically conductive peel-off material is larger than a size of the through hole within a range of 1 μm to 50 μm, accuracy of a control of dimensional tolerance of the through hole can be sufficiently alleviated and, at the same time, an amount of an electrically conductive peel-off material that is formed into the peeled-off chips S at the time of performing press fitting can be reduced.

According to the method of manufacturing an electronic module of the embodiment, in a case where each of the pin terminal 172, 174, 182, 184 further includes a flange portion that is brought into contact with each of the support members 171, 173, 181, 183 after press fitting, each of the support members 171, 173, 181, 183 and the flange portion are brought into contact with each other and hence, inclining of the pin terminals 172, 174, 182, 184 can be suppressed.

With respect to the method Of manufacturing an electronic module of the embodiment, in a case where, in the pin terminal press-fitting step S20, a support member having a surface on which an electrically conductive bonding material is disposed is used as the support member 171, 173, 181, 183, and, the method of manufacturing an electronic module according to the embodiment further includes: the electrically conductive bonding material melting step S30 that bonds the support members 171, 173, 181, 183 and the pin terminals 172, 174, 182, 184 to each other after the pin terminal press-fitting step S20, the support members 171, 173, 181, 183 and the pin terminals 172, 174, 182, 184 can be electrically connected with each other with certainty and hence, a contact resistance can be reduced. Further, the peeled chips S that are peeled off in the pin terminal press-fitting step S20 are absorbed by the electrically conductive bonding material, the electrically conductive peel-off material or both of these materials and hence, the occurrence of a short-circuit failure attributed to the movement of the peeled chips S can be also suppressed.

Although the present invention has been described based on the above-mentioned embodiment heretofore, the present invention is not limited to the above-mentioned embodiment. The present invention can be performed in various modes without departing from the gist of the present invention. For example, the following modifications are also conceivable.

(1) The shapes, the numbers, the sizes, the positions and the like of the constitutional elements according to the present invention are not limited to the values described in the above-description and respective drawings, and can be suitably changed provided that the technical features of the present invention are not impaired.

(2) In the above-mentioned embodiment, the case has been described where the electronic element 120 is formed of a power MOSFET. However, the present invention is not limited to such a case. The electronic element may be formed of, besides the power MOSFET, other semiconductor elements such as a MOSFET, an IGBT, a thyristor, a diode or the like. As a material of the semiconductor element, a raw material such as silicon, SiC, GaN can be used. Further, as the electronic elements, electronic elements other than the semiconductor element such as a capacitor or a reactor may be used.

(3) In the above-mentioned embodiment, the through hole 171a has a square shape. However, the present invention is not limited to such a case. For example, the through hole may have a circular shape.

(4) In the above-mentioned embodiment, the method of manufacturing an electronic module includes the constitutional element arrangement step S10, the pin terminal press-fitting step S20, and the resin sealing step S40 (further including the electrically conductive bonding material melting step S30 when necessary). However, the present invention is not limited to such a case. For example, the method of manufacturing an electronic module may further include a constitutional element arrangement step after the pin terminal press-fitting step. Further, the method of manufacturing an electronic module may include a step other than the above-mentioned steps (for example, a step of separating the support members and the like from a frame).

(5) In the above-mentioned embodiment, the electrically conductive peel-off material 172b is disposed so as to cover the entire surface of the pin body 172a and the entire surface of the flange portion 172c. However, the present invention is not limited to such a case. The electrically conductive peel-off material may be disposed so as to cover a portion of the pin body, particularly a portion of the pin body that is fitted into the through hole by press fitting.

(6) In the above-mentioned embodiment, the pin terminal 172, 174, 182, 184 has the flange portion. However, the present invention is not limited such a case. The pin terminal may not include the flange portion.

(7) In the above-mentioned embodiment, the description has been made with respect to the preferred configuration that the maximum diameter of the pin terminal 172 that includes the electrically conductive peel-off material 172b is larger than the size of the through hole 171a. However, the present invention is not limited to such a case. The maximum diameter of the pin terminal that includes the electrically conductive peel-off material may have the same size as the through hole. That is, a difference between the maximum diameter of the pin terminal that includes the electrically conductive peel-off material and the size of the through hole may be 0 μm. Even in the case where the maximum diameter of the pin terminal has the same size as the through hole, in actually performing the step, a deviation of the pin terminal in the press fitting direction or the like is generated and hence, the peeling off of the electrically conductive peel-off material is generated in the pin terminal press-fitting step.

1. An electronic module comprising:
an electronic element;
a support member in which a through hole that penetrates the support member in a plate thickness direction is formed; and
a pin terminal having a columnar shape, the pin terminal being supported on the support member in a state that the pin terminal is made to pass through the through hole and being electrically connected with the electronic element, wherein
the pin terminal includes: a pin body; and an electrically conductive peel-off material that is disposed on a surface of the pin body, and the pin terminal is supported by the support member in a state where the electrically conductive peel-off material is interposed at least at a portion between the through hole and the pin body, the pin terminal.

2. A method of manufacturing an electronic module for manufacturing an electronic module that includes: an electronic element; a support member in which a through hole that penetrates the support member in a plate thickness direction is formed; and a pin terminal having a columnar shape, the pin terminal being supported on the support member in a state that the pin terminal is made to pass through the through hole and being electrically connected with the electronic element, the method of manufacturing an electronic module comprising:
a pin terminal press fitting step of fitting the pin terminal having a pin body and an electrically conductive peel-off material that is disposed on a surface of the pin body into the through hole formed in the support member by press fitting, wherein
in the pin terminal press fitting step, the pin terminal is fitted into the through hole formed in the support member while peeling off a portion of the electrically conductive peel-off material by a peripheral edge of the through hole.

3. The method of manufacturing an electronic module according to claim 2, wherein
the electrically conductive peel-off material is made of a plating material.

4. The method of manufacturing an electronic module according to claim 2, wherein
the electrically conductive peel-off material is made of Ni, Au, Pd, Sn, Ag or solder.

5. The method of manufacturing an electronic module according to claim 2, wherein
the electrically conductive peel-off material is made of a material having hardness lower than hardness of the pin body

6. The method of manufacturing an electronic module according to claim 2, wherein
thickness of the electrically conductive peel-off material before the pin terminal is fitted into the through hole by press fitting falls within a range of from 10 μm or more to a thickness two times or less as large as a maximum diameter of the pin body.

7. The method of manufacturing an electronic module according to claim 2, wherein
a maximum diameter of the pin body is smaller than a size of the through hole, and a maximum diameter of the pin terminal including the electrically conductive peel-off material is larger than a size of the through hole.

8. The method of manufacturing an electronic module according to claim 7, wherein
the maximum diameter of the pin terminal including the electrically conductive peel-off material is larger than a size of the through hole by a value within a range of 1 μm to 50 μm.

9. The method of manufacturing an electronic module according to claim 2, wherein
the pin terminal further includes a flange portion that is brought into contact with the support member after press fitting.

10. The method of manufacturing an electronic module according to claim 2, wherein
in the pin terminal press-fitting step, as the support member, a support member having a surface on which an electrically conductive bonding material is disposed is used, and
the method of manufacturing an electronic module further includes an electrically conductive bonding material melting step that melts the electrically conductive bonding material and bonds the support member and the pin terminal to each other after the pin terminal press-fitting step.
